(19) United States
(12) Patent Application Publication
(10) Pub. No.: US 2008/0122456 A1
(43) Pub. Date: May 29, 2008

(54) Capacitive Sensor

(76) Inventors: Anthony Moon, Cardiff (GB); David Snell, Cardiff (GB); Cynthia Anne Snell, Fareham (GB)

Correspondence Address: STETINA BRUNDA GARRED & BRUCKER, 75 ENTERPRISE, SUITE 250, ALISO VIEJO, CA, 92656, US

(21) Appl. No.: 10/566,407

(22) PCT Filed: Jul. 28, 2004
(86) PCT No.: PCT/GB2004/003260

§ 371 Date: Jun. 25, 2007

(30) Foreign Application Priority Data
Jul. 28, 2003 (GB) 0317644.3

(51) Int. Cl. H03K 17/955

(52) U.S. Cl. 324/674

(57) ABSTRACT

A capacitive sensor for mounting to a body, particularly a body such as a van door (55). The sensor has a sensor plate (51) to which a first signal is applied. A first guard plate (52) is interposed between the sensor plate (51) and the body (55), and a second guard plate (53) is interposed between the first guard plate (52) and the body (55). The first and second guard plates (52, 53) each have signals applied thereto which are the same or at least similar to the first signal applied to the sensor plate (51). In this way, the second guard plate (53) acts as a rear guard to the first guard (52) and reduces its capacitance to ground. This reduces the current drawn by the first guard (52), allowing it to more accurately track the signal on the sensor and consequently better mask the sensor plate (51) from the body (55).

The present invention relates to the field of capacitive sensors in particular capacitive sensors for attachment to a vehicle for sensing the proximity of the vehicle to other objects when manoeuvring the vehicle.

Capacitive sensors have been used in parts of cars for collision avoidance purposes, and in recent years a number of luxury cars have been fitted with sensors particularly on the rear of the vehicle to warn the driver of objects. In operation when the vehicle is being reversed, a collision with unseen or obscured objects, such as walls or bollards, can be avoided whilst still being able to position the vehicle close to such objects.

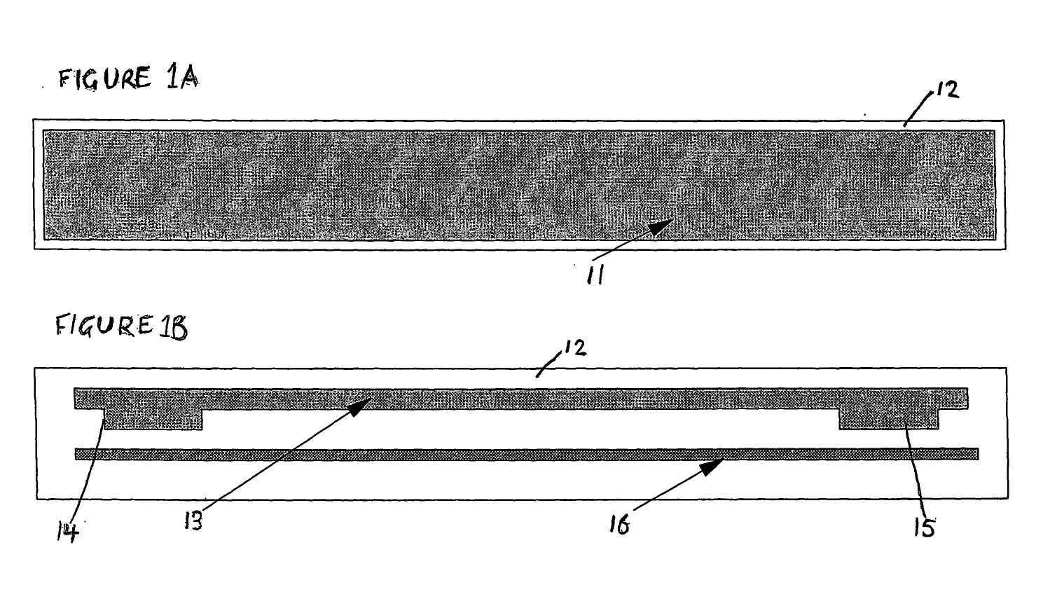

A capacitive sensor typically consists of two strips of metal, or other conductive material, insulated from each other and provided inside the bumper of a vehicle. The two strips of metal form a guard plate and the sensor plate. FIGS. 1A and 1B illustrate front and back views of an example of such a guard and sensor plate arrangement.

FIG. 1A illustrates the back of such a sensor and guard plate combination. The plate which is outermost relative to the vehicle is called the sensor plate or sensor conductor and the plate which is innermost i.e. closest to the vehicle itself, is called the guard plate or guard conductor. Hence, in FIG. 1A the guard plate 11 faces the vehicle so as to shield the sensor plate (not visible) to ensure it only detects changes in the outward direction (i.e. away from the vehicle). In other words, the conductive guard plate acts as a shield to reduce the sensitivity of the device to anything behind the sensor plate. The conductive guard plate is driven with an AC signal identical to that driving the sensor plate.

The guard plate 11 is formed on an insulative film 12, which is only visible in FIG. 1A as a border around the guard plate. It is however to be appreciated that in some sensor arrangements, the guard plate wholly covers the insulative film surface so that the film is not visible from the back view of the sensor and guard plate arrangement.

FIG. 1B illustrates the font of the sensor and guard plate combination. The sensor plate 13 (as with the guard plate 11) can be applied to the sheet of insulative film 12 in a number of ways, including screen printing with conductive ink, laminating conductive materials or using a combination of these two techniques.

The sensor plate 13 in FIG. 1B is illustrated in a preferred form, being elongate with two lobes (14, 15) of increased width at either end of the sensor plate. This provides increased sensitivity at the edges of the vehicle. With a uniform elongate strip the sensitivity would be typically reduced at the edges because obstructions can only couple capacitively with one side of the sensor, whereas an object directly opposite the middle of the sensor would couple capacitively with both sides of the sensor.

An optional feature is also shown in FIG. 1B, being an extra conductive strip 16 which can be positioned above or below the sensor plate 13 or both. This conductive surface carries an amplified guard signal and has the effect of making the guard appear. bigger. It is therefore effective in nullifying the effect of drips of water running across the front of the sensor. This feature is described in greater detail in GB 2,374,422 and will not be described in any further detail here.

In use, the guard and sensor plates are connected to a control unit, which supplies high frequency signals to the sensor and guard plates. Objects in the vicinity of the vehicle present a capacitance to ground. In fact this capacitance is formed by two capacitances in series, that is: the capacitance between the sensor plate and the object (or objects) being sensed; and the capacitance between the object and ground. The control unit monitors the capacitance between the sensor plate and ground. As the distance between the vehicle (and hence the sensor) and an object changes, the measured capacitance changes. The control unit senses the change in capacitance. Therefore the control unit can use the change in capacitance to provide an indication of the distance between any objects in the vicinity of the vehicle and the sensor plate, and hence the rear of the vehicle.

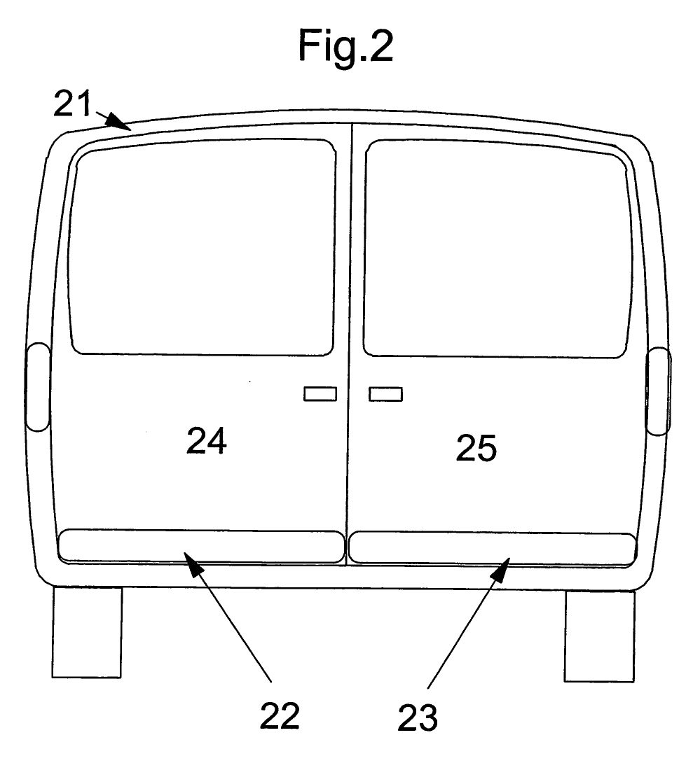

FIG. 2 illustrates the rear of a vehicle 21, such as a minibus or van, with two sensor strips 22, 23 positioned in the lower region of the rear of the vehicle. In this instance the sensor strips are positioned in the lower region of the vehicle's rear doors 24, 25.

A well recognised problem with large vehicles, such as minibuses or vans is that their rearwards visibility is often restricted from the driver's seat. This problem is generally magnified for persons used to driving a vehicle of smaller dimensions, such as that of a standard car. This is often the case with vehicles available from hire companies.

As seen in FIG. 2, the parking aid sensor of FIG. 1 can be fitted on the rear doors of the vehicle. A problem with this design, however, when used adjacent a large metal object, such as the vehicle door, is that the metal door acts as a large ground conductor. Therefore, if the sensor is placed against it, a very effective guard conductor is needed to isolate the sensor from the vehicle door (ground). In addition, it would also need to be driven by a very good amplifier with low output impedance.

It has been found that sensors of the form of FIG. 1 provide some degree of isolation for the sensor plate, but the sensitivity of the sensor could be improved.

One solution to this problem is to space the sensor further away from the door. This, however, leads to a sensor and housing combination that protrudes from the vehicle. This is not desirable, particularly for aesthetic purposes. As a general guide, the housed sensor should not protrude more than 20 mm from the vehicle door.

Therefore, there is a need for a capacitive sensor that minimises the separation of the sensor from the vehicle door and yet provides an acceptable degree of sensitivity.

There is therefore a need for a capacitive sensor suitable for fitting on or near large regions of metal. In particular there is a need for a sensor suitable for fitting on a metal door of a vehicle. More particularly, there is a need for such a sensor that does not require an amplifier of very low output impedance to drive it.

The present invention seeks to overcome or alleviate at least one of the problems of the prior art.

According to one aspect, the present invention provides a capacitive sensor for mounting to a body, in use, comprising:
a sensor plate configured to have a first signal applied thereto;
first guard plate interposed between the sensor plate and the body, which is configured to have a first guard plate signal applied thereto; and
a second guard plate interposed between the first guard plate and the body, which is configured to have a second guard plate signal applied thereto.

It is also preferable that the capacitive sensor further comprises at least one control means configured to apply the first and second guard plates signals to the first and second guard plates respectively.

According to a related aspect, the present invention provides a method of operating a capacitive sensor when mounted to a body the capacitive sensor comprising a sensor plate, a first guard plate interposed between the sensor plate and the body and a second guard plate interposed between the first guard plate and the body, the method comprising:
applying a first signal to the sensor plate;
applying a first guard plate signal to the first guard plate;
applying a second guard plate signal to the second guard plate.

Preferably the first guard plate signal is related to the first signal applied to the sensor plate by a first amplification factor and the second guard plate signal is related to the first signal by a second amplification factor. More preferably the first and second amplification factors are both substantially one.

In this regard, it is preferable that the first and second guard signals are substantially identical to the first signal applied to the sensor plate in terms of frequency, phase and amplitude.

In these arrangements and methods, the second guard plate acts as a rear guard to the first guard and reduces its effective capacitance to ground. This reduces the current drawn by the first guard, allowing it to more accurately track the signal on the sensor plate and consequently better mask the sensor plate from the body.

For instance, the signal applied to the first guard plate will track the signal on the sensor plate, particularly where the signals applied to the two guard plates are substantially identical to the sensor plate signal in terms of frequency, phase and amplitude.

Any signal applied to the second guard plates will aid in masking the sensor plate from the body, but most preferably the second guard plate signal approximates the signal applied to the sensor. This does not include the guard plate being grounded, which is contrary to these aspects of the invention. Further, the signal applied to the second guard plate can have a slightly larger amplification factor than the signal applied to the first guard plate and the sensor signal, such as by an amplification factor of 1.2. This can have a beneficial effect on the sensor's sensitivity.

Preferably the sensor further comprises an insulative substrate between the first guard plate and the second guard plate, for electrically isolating the first guard plate from the second guard plate.

It is also preferable that the first and second guard plates are arranged substantially in parallel and the first signal is an integrated square wave.

In a further preferred embodiment, the sensor additionally comprises first and second amplifier units, wherein the first signal applied to the sensor plate is also applied to the first amplifier unit, and wherein the output of the first amplifier unit is fed to the first guard plate and the second amplifier unit, and wherein the output of the second amplifier unit is fed to the second guard plate.

In an alternative preferred embodiment, the sensor additionally comprises first and second amplifier units, wherein the first signal is applied to the sensor plate and the output of the sensor plate is fed to the first and second amplifier units, and wherein the output of the first amplifier unit is fed to the first guard plate and the output of the second amplifier unit is fed to the second guard plate.

Preferably this alternative preferred embodiment additionally comprises a third amplifier, wherein the first signal is fed to the first and second amplifier units via the third amplifier unit.

Preferably each amplifier is a unity gain amplifier or has an amplification factor or gain of substantially one.

The capacitive sensor may also comprise calculation means for providing proximity information based upon the capacitance between the sensor plate and electrical ground. The sensor plate may also be of varied shape along its length to provide increased sensitivity portions.

It is also preferable that the sensor comprises a casing attachable to the body and for enclosing the sensor plate and the first and second guard plates. Preferably the casing has a recess at an upper end and a recess at a lower end, such that, when the sensor is mounted on the body, the recesses are configured to direct liquid flowing down the body to flow generally between the second guard plate and the body upon which the sensor is mounted.

In another aspect, the present invention provides a capacitive sensor system comprising:
a signal source arranged to produce a main signal; and
first and second amplifier units, wherein the main signal is fed to a sensor plate connection and the first amplifier unit, and wherein the output of the first amplifier unit is fed to a first guard plate connection and the second amplifier unit, and wherein the output of the second amplifier unit is fed to a second guard plate connection.

In a further aspect, the present invention provides a capacitive sensor control system for connection to a capacitive sensor comprising a sensor plate, a first guard plate interposed between the sensor plate and the body and a second guard plate interposed between the first guard plate and the body, the control system comprising:
a signal source arranged to produce a main signal; and
first and second amplifier units,
wherein the main signal is fed to the sensor plate and to the first and second amplifier units, and wherein
the output of the first amplifier unit is fed to the first guard plate and the output of the second amplifier unit is fed to the second guard plate.

This further aspect of the invention preferably comprises a third amplifier unit, wherein the output of the sensor plate is fed to the third amplifier unit before being fed to the first and second amplifier units.

Preferably each amplifier is a unity gain amplifier or has an amplification factor or gain of substantially one.

According to a still further aspect, the present invention provides a method for operating a capacitive sensor system, the method comprising:
generating a main signal;
applying the main signal to a sensor plate;
amplifying the main signal;
applying the amplified main signal to a first guard plate;
amplifying the signal applied to the first guard plate; and
applying the amplified signal of the first guard plate to a second guard plate.

According to another aspect, the present invention provides a method for operating a capacitive sensor system, the method comprising:
generating a main signal;
applying the main signal to a sensor plate;
branching the main signal into first and second signals;
amplifying the signal applied to the sensor plate to produce first and second signals;
applying the first signal to a first guard plate; and
applying the second signal to a second guard plate.

Preferably, in this other aspect, the method further comprises amplifying the output of the sensor plate before branching into first and second signals.

These aspects of the present invention will now be described with reference to the accompanying drawings in which:

FIG. 1A illustrates the back view of a known sensor and guard plate arrangement for a parking aid sensor;

FIG. 1B illustrates the front view of the sensor and guard plate arrangement of FIG. 1A;

FIG. 2 illustrates the rear of a van or minibus with first and second parking aid sensors attached to the rear doors of the vehicle;

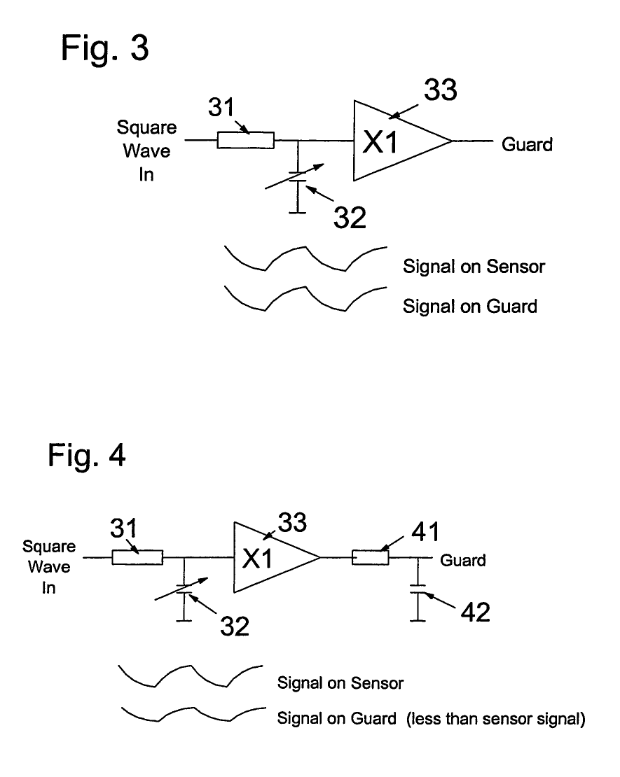

FIG. 3 illustrates a circuit representation of an ideal capacitance sensor for attachment to a vehicle bumper;

FIG. 4 illustrates a circuit representation of a capacitance sensor with parasitic components;

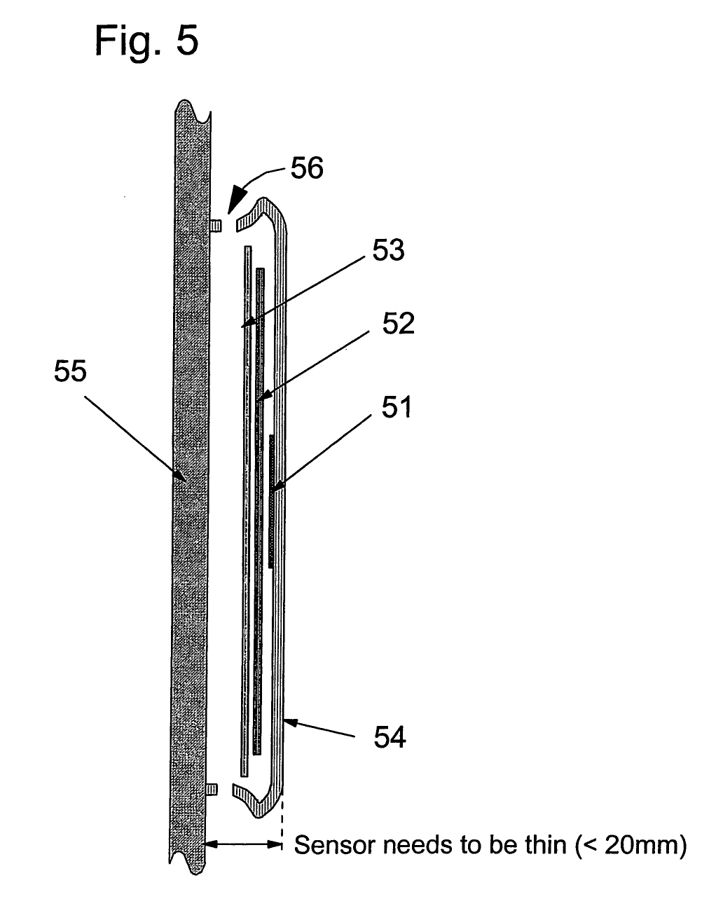

FIG. 5 illustrates a cross-sectional view of a capacitance sensor according to an embodiment of the present invention;

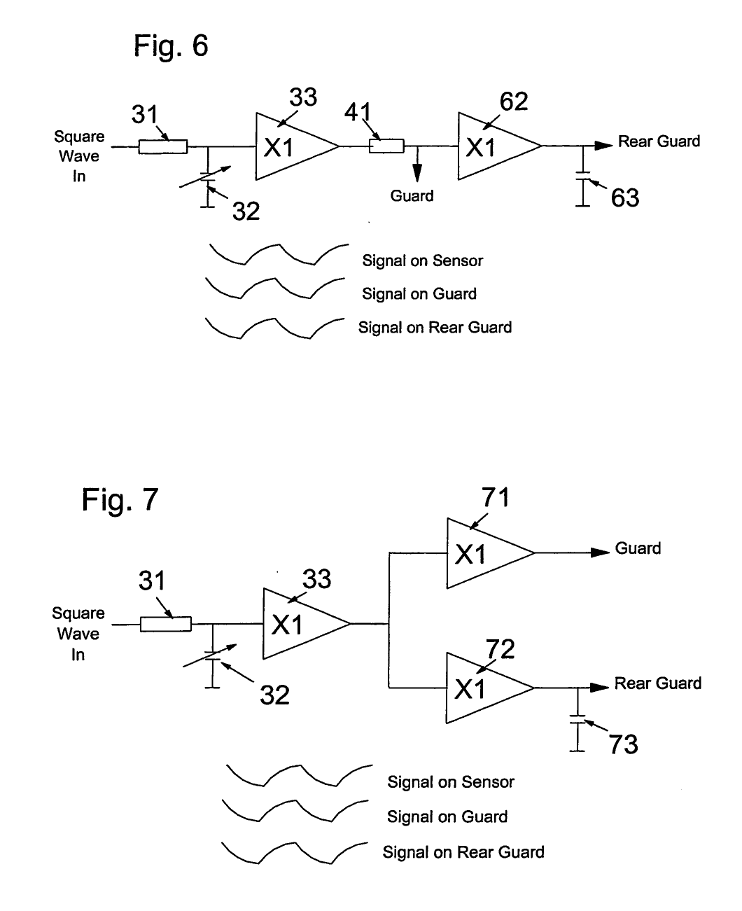

FIG. 6 illustrates a first arrangement for amplifying the signal applied to main guard and the rear guard plates according to an embodiment of the invention;

FIG. 7 illustrates a second arrangement for amplifying the signal applied to main guard and the rear guard plates according to an embodiment of the invention.

FIGS. 3 and 4 illustrate the problems experienced by placing the sensor on or near a large metal sheet that acts as a ground. As described previously, the guard conductor is provided with an AC signal identical to that provided to the sensor conductor, so that it can shield the sensor conductor. To achieve this, the signal applied to the sensor is also applied to the guard conductor. Before the signal is applied to the guard conductor, though, it is amplified with a unity gain amplifier, so that no voltage amplification occurs, but the power in the signal is greatly increased.

An example of an ideal circuit arrangement in this regard, is shown in FIG. 3. In this circuit the input signal, which is preferably a square wave AC signal, is fed to the sensor plate 1 through a high value series resistor 31. The capacitance between the sensor plate and ground acts as a series capacitor 32. This capacitor 32 forms an RC circuit with the resistor 31. Consequently, the voltage between the sensor plate and ground is an integrated square wave, as shown in FIG. 3 as the “signal on sensor”.

The signal applied to the sensor plate is also applied to the guard, but through an amplifier circuit 33, which is a unity gain amplifier. The output of the amplifier circuit, which is illustrated as the “signal on guard” in FIG. 3, is provided to the guard conductor. In this way, the voltage on the guard plate closely approximates the voltage on the sensor plate by virtue of the unity gain amplifier, as can be seen from FIG. 3, but has greater power due to the unity gain amplifier 33.

An ideal amplifier should have an output impedance of zero ohms, but in practice this is difficult to achieve. Additional capacitance between the guard and ground is always present to some degree.

Where a capacitive sensor is positioned in a vehicle bumper, the capacitance between the guard and ground is fairly small because the bumper skin, where the sensor is located, is spaced away from the metallic car body (ground). Therefore, with a sensor as shown in FIG. 1 in a bumper application, there is minimal grounding effect, so the signal on the guard will be virtually identical to the signal on the sensor. The sensor and guard signals therefore approximate the amplifier circuit of FIG. 3 to a satisfactory degree. Thus any change in the potential on the sensor plate will be matched by an equivalent change in the potential on the guard plate. This allows the guard plate to effectively shield the sensor plate from changes occurring behind the guard plate without adversely reducing the sensitivity of the device. This also means the leads connecting the sensor plate to the control circuitry can be shielded by the guard plate connection, using for example co-axial cable, so that the control circuitry can be located away from the sensor plate.

In the situation of the sensor being positioned on a door of a vehicle, such as on a rear door of a van or minibus, the guard is much closer to ground (i.e. the metallic vehicle door) and so a greater capacitance occurs between the guard and ground. The effect of this capacitance, combined with the output impedance of the guard conductor, is illustrated using FIG. 4. The signal applied to the sensor, which is also input to the amplifier circuit 33 is the same as in FIG. 3. The output of the amplifier 33, however, which is fed to the guard plate, has parasitic components due to its output impedance 41 and the capacitance between the guard plate and van door (capacitor 42). In view of these parasitic components 41, 42, the signal applied to the guard has a lower amplitude than the signal on the sensor conductor, as illustrated by the waveforms in FIG. 4 representing the “signal on sensor” and the “signal on guard”. Hence, the guard tends to become transparent to the sensor, in that the sensor “sees” too much ground through the guard and becomes less sensitive as a result.

To address this problem, according to an embodiment of the invention, there is provided a sensor of the form shown in FIG. 5.

The sensor comprises a sensor plate 51 on a surface of a first substrate (not illustrated for simplicity), so that the sensor plate 51 is facing away from the vehicle. A main guard plate 52 is situated on the opposite surface of the substrate, so that it faces towards the vehicle. This main guard plate 52 is situated adjacent a second substrate (not shown), such that the second substrate is adjacent the surface facing the vehicle. The main guard plate 52 is therefore effectively sandwiched between the first and second substrates and is positioned between the sensor plate 51 and the body of the vehicle.

An additional guard plate, being rear guard plate 53 is positioned on the surface of the second substrate facing the vehicle. Therefore, the rear guard plate 53 is positioned between the main guard plate 52 and the body of the vehicle. The rear guard plate 53 is at least as large as the main guard plate 52, and preferably of greater dimensions. Both guard plates have an AC signal applied which is identical, or at least similar, to the AC signal on the sensor plate 51.

This configuration enables a sensor to be provided where the separation between the sensor and the vehicle door skin is minimised, while retaining sensitivity. The rear guard plate 53 effectively operates as a guard to the main guard, thereby reducing its effective capacitance to ground. This reduces the current drawn from the main guard amplifier, so it more accurately tracks the signal on the sensor, and consequently better masks the sensor from the van door.

This sensor is positioned in a casing 54, which attaches the sensor to the vehicle, such as onto the metal skin of the vehicle door 55. Preferably this casing 54 includes a drainage aperture 56 at the top and bottom of the casing in order to direct rainwater behind the sensor plate so as to minimise interference. This feature minimises the rain water that runs down the vehicle door from running over the sensor.

The aperture could be made up of a single aperture at each end of the casing or even a plurality of recesses at each end. Further, as shown in FIG. 5, the casing or cover is shaped at the top end with a sloping edge so that liquid is directed towards the aperture. The bottom end has a corresponding shape. This simplifies the manufacture of the casing and the assembly of the sensor.

The casing is also shaped so that water that does actually pass across the sensor surface does not then run down the lower car body or door, as this could also interfere with the operation of the sensor plate. In FIG. 5, the casing is shaped with a tapered lower end so that any water that does pass across the sensor surface drips off the bottom of the casing. The tapered lower end is intended to prevent the water passing across the sensor surface from coming into contact with the vehicle body, as this would result in undesirable coupling between the body and the water.

It is to be appreciated that the form of casing just described is only intended to be illustrative, and other forms and arrangements are possible.

As mentioned previously, the rear guard plate 53 and the main guard plate 52 should have an AC signal applied which is as close as possible to that applied to the sensor plate. FIG. 6 illustrates an amplifier arrangement suitable for driving both the main guard plate 52 and the rear guard plate 53. The amplifier arrangement is a two-stage assembly with two unity gain amplifiers positioned in series. Where features correspond with those in previous figures, like numerals have been used.

The signal on the sensor plate, like the arrangements in FIGS. 3 and 4, is a square wave signal fed to the sensor plate through a high value series resistor 31 and with the capacitance between the sensor plate and ground acting as a series capacitor 32. The result is an integrated square wave.

This integrated square wave signal is the fed to one of the guard plates, such as the main guard plate via the first stage of the assembly, which comprises unity gain amplifier 33 and resistor 61. The resistor 61 represents the output impedance of the amplifier 33. The resultant signal is then fed the main guard plate. The signal is also fed to the second stage of the assembly, which comprises unity gain amplifier 62 and a series capacitor 63. The capacitor 63 represents the capacitance between the rear guard plate and ground. The resultant signal is applied to the rear guard plate. The resultant signals on both the main guard and rear guard plate closely correspond with the signal on the sensor plate, as illustrated in FIG. 6.

FIG. 7 illustrates an alternative guard amplifier arrangement. The arrangement for producing the sensor plate signal is the same as for FIG. 6. This signal is then applied to a first amplifier 33. The output of the first amplifier is then input to second and third amplifiers 71, 72, which are in parallel. The output of the second amplifier 71 is applied to the main guard conductor and the output of the third amplifier is applied to the rear guard conductor. This output also has a series capacitor 73 representing the capacitance between the rear guard and ground.

With this configuration, it is to be appreciated that the circuit may be implemented with the first amplifier 33 be removed. However, because of the high input impedance, it is preferable to utilise all three amplifiers.

Alterations and additions are possible within the general inventive concepts. The embodiments of the invention are to be considered as illustrations of the inventions and not necessarily limiting on the general inventive concepts.

For example, instead of a single rear or secondary guard plate to the main guard plate, multiple secondary guard plates could be utilised.

Further, the size and shape of the rear guard plate or plates could be customised in order to suit a particular vehicle. For instance, if the sensor was to be attached to a vehicle door that was only metallic in a particular region, or such that it only partially overlaid the metallic vehicle door, the rear guard plate could be positioned and shaped so as to shield the sensor plate from this particular region.

A further application for which the present invention may be utilised is in relation to passenger doors of a vehicle, which are adapted for being opened from the inside. Sensors according to the present invention, suitable for being positioned adjacent to large panels of metal, can be positioned on such vehicle doors, so as to detect if the vehicle door would be likely to hit anything when opened. Alternatively the detection process can be undertaken when the door was being opened.

1. A capacitive sensor for mounting to a body, in use, comprising:
a sensor plate configured to have a first signal applied thereto;
first guard plate interposed between the sensor plate and the body, which is configured to have a first guard plate signal applied thereto; and
a second guard plate interposed between the first guard plate and the body which is configured to have a second guard plate signal applied thereto.

2. The capacitive sensor of claim 1 further comprising at least one control means configured to apply the first and second guard plate signals to the first and second guard plates respectively.

3. The capacitive sensor of claim 1 wherein the first guard plate signal is related to the first signal applied to the sensor plate by a first amplification factor and the second guard plate signal is related to the first signal by a second amplification factor.

4. The capacitive sensor of claim 3 wherein the first and second amplification factors are substantially one.

5. The capacitive sensor of claim 3 wherein the second amplification factor is greater than the first amplification factor.

6. The sensor of claim 1 wherein the first and second guard plates signals are substantially identical to the first signal applied to the sensor plate in terms of frequency, phase and amplitude.

7. The sensor of claim 1 further comprising an insulative substrate between the first guard plate and the second guard plate, for electrically isolating the first guard plate from the second guard plate.

8. The sensor according to claim 1 wherein the first and second guard plates are arranged substantially in a parallel.

9. The sensor according to claim 1 further comprising:
first and second amplifier units,
wherein the first signal applied to the sensor plate is also applied to the first amplifier unit, and wherein
the output of the first amplifier unit is fed to the first guard plate and the second amplifier unit, and wherein
the output of the second amplifier unit is fed to the second guard plate.

10. The sensor according to claim 1 further comprising:
first and second amplifier units, and wherein
the first signal applied to the sensor plate is fed to the first and second amplifier units, and wherein
the output of the first amplifier unit is fed to the first guard plate and the output of the second amplifier unit is fed to the second guard plate.

11. The sensor of claim 10 further comprising a third amplifier, wherein the first signal is fed to the first and second amplifier units via the third amplifier unit.

12. A capacitive sensor according to claim 9, 10 or 11 wherein each amplifier has a gain of substantially one.

13. A capacitive sensor of claim 1 further comprising calculation means for providing proximity information based upon the capacitance between the sensor plate and electrical ground.

14. A capacitive sensor according to claim 1 wherein the first signal is an integrated square wave.

15. A capacitive sensor according to claim 1 further comprising a casing attachable to the body and for enclosing the sensor plate and the first and second guard plates.

16. A capacitive sensor as claimed in claim 14 wherein the casing further comprises a recess at an upper end and a recess at a lower end, such that, when the sensor is mounted on the body, the recesses are configured to direct liquid flowing down the body to flow generally between the second guard plate and the body upon which the sensor is mounted.

17. A capacitive sensor system comprising:
a signal source arranged to produce a main signal; and
first and second amplifier units,
wherein the main signal is fed to a sensor plate connection and the first amplifier unit, and wherein
the output of the first amplifier unit is fed to a first guard plate connection and the second amplifier unit, and wherein
the output of the second amplifier unit is fed to a second guard plate connection.

18. A capacitive sensor control system for connection to a capacitive sensor comprising a sensor plate, a first guard plate interposed between the sensor plate and the body and a second guard plate interposed between the first guard plate and the body, the control system comprising:
a signal source arranged to produce a main signal; and
first and second amplifier units,
wherein the main signal is fed to the sensor plate and to the first and second amplifier units, and wherein
the output of the first amplifier unit is fed to the first guard plate and the output of the second amplifier unit is fed to the second guard plate.

19. The sensor system of claim 18 further comprising a third amplifier unit, wherein the main signal is fed to the first and second amplifier units via the third amplifier unit.

20. A capacitive sensor system according to claim 17, 18 or 19 wherein each amplifier has a gain of substantially one.

21. A method of operating a capacitive sensor when mounted to a body the capacitive sensor comprising a sensor plate, a first guard plate interposed between the sensor plate and the body and a second guard plate interposed between the first guard plate and the body, the method comprising:
applying a first signal to the sensor plate;
applying a first guard plate signal to the first guard plate;
applying a second guard plate signal to the second guard plate.

22. The method of claim 21 wherein the first guard plate signal is related to the first signal by a first amplification factor and the second guard plate signal is related to the first signal by a second amplification factor.

23. The method of claim 22 wherein the first and second amplification factors are substantially one.

24. The method of claim 21 wherein the first guard plate signal is substantially identical to the first and second guard plate signals in terms of frequency, phase and amplitude.

25. A method for operating a capacitive sensor system, the method comprising:
generating a main signal;
applying the main signal to a sensor plate;
amplifying the main signal;
applying the amplified main signal to a first guard plate;
amplifying the signal applied to the first guard plate; and
applying the amplified signal of the first guard plate to a second guard plate.

26. A method for operating a capacitive sensor system, the method comprising:
generating a main signal;
applying the main signal to a sensor plate;
branching the main signal into first and second signals;
amplifying the signal applied to the sensor plate to produce first and second signals;
applying the first signal to a first guard plate; and
applying the second signal to a second guard plate.

27. The method of claim 26 further comprising amplifying the main signal before branching into first and second signals.

28. The method of claim 25, 26 or 27 wherein the signals are amplified with a unity gain.

29. (canceled)

30. A vehicle comprising a capacitive sensor according to claim 1.

31. (canceled)

32. (canceled)
